(19) United States
(12) Patent Application Publication
(10) Pub. No.: US 2005/0093584 A1
(43) Pub. Date: May 5, 2005

(54) Fast-hopping frequency synthesizer

(75) Inventor: Dan Meacham, Del Mar, CA (US)

Correspondence Address: VAN PELT & YI LLP, 10050 N. FOOTHILL BLVD #200, CUPERTINO, CA, 95014, US

(73) Assignee: Staccato Communications

(21) Appl. No.: 10/698,990

(22) Filed: Oct. 31, 2003

(51) Int. Cl. H03B 1/00

(52) U.S. Cl. 327/105

(57) ABSTRACT

A frequency synthesizer is disclosed. The frequency synthesizer comprises a fixed frequency generator configured to generate a fixed frequency signal, a variable frequency generator configured to generate a variable frequency signal, wherein the fixed frequency signal and the variable frequency signal are combined to provide a fast-hopping output signal.

### FIELD OF THE INVENTION

The present invention relates generally to frequency synthesizers. More specifically, a fast-hopping frequency synthesizer is disclosed.

### BACKGROUND OF THE INVENTION

Frequency synthesizers are widely used in communication systems. Existing frequency synthesizers typically include a reference frequency and a phase locked loop (PLL). The PLL takes the reference frequency as its input, and is configurable to provide a range of output frequencies based on the reference input via a feedback loop.

A PLL typically includes a voltage controlled oscillator (VCO) that is configured in a feedback loop to provide an output signal at the desired frequency. In some systems, the desired output frequency changes over time. The switching from one output frequency to another is referred to as frequency hopping or channel hopping. Since the PLL typically is unable to instantaneously lock onto a frequency, it usually takes some time for the frequency synthesizer to switch from one output frequency to another. This time is typically determined by the bandwidth of the loop filter.

While existing frequency synthesizers are adequate for communication systems that tolerate relatively long switching times, they typically do not meet the demands of systems that require very fast frequency hopping with a time-constant substantially greater than practical crystal (loop reference) frequencies or loop bandwidths. It would be desirable to have a frequency synthesizer that could meet the speed demands of fast-hopping systems, without significant increase in complexity and cost.

### BRIEF DESCRIPTION OF THE DRAWINGS

Various embodiments of the invention are disclosed in the following detailed description and the accompanying drawings.

FIG. 1 is a system diagram of a high-speed transceiver embodiment.

FIG. 2A is a block diagram illustrating a fast-hopping frequency synthesizer embodiment.

FIG. 2B is a block diagram illustrating another fast-hopping frequency synthesizer embodiment.

FIG. 3A is a block diagram illustrating another fast-hopping frequency synthesizer embodiment.

FIG. 3B is a diagram illustrating the operations of logic processor 330 shown in FIG. 3A according to one embodiment.

FIG. 4 is a block diagram illustrating another fast-hopping frequency synthesizer embodiment.

FIG. 5 is a block diagram illustrating another fast-hopping frequency synthesizer embodiment.

FIG. 6 is a block diagram illustrating another fast-hopping frequency synthesizer embodiment.

### DETAILED DESCRIPTION

The invention can be implemented in numerous ways, including as a process, an apparatus, a system, a composition of matter, a computer readable medium such as a computer readable storage medium or a computer network wherein program instructions are sent over optical or electronic communication links. In this specification, these implementations, or any other form that the invention may take, may be referred to as techniques. In general, the order of the steps of disclosed processes may be altered within the scope of the invention.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and invention may be practiced according to the claims without some or all of these specific details. For the purpose of clarity, technical material that is known in the technical fields related to the invention has not been described in detail so that the invention is not unnecessarily obscured.

An improved system and method for providing a fast-hopping signal are disclosed. In some embodiments, a fast-hopping frequency synthesizer that includes a fixed frequency generator and a variable frequency generator is used. In some embodiments, the variable frequency generator provides a variable frequency signal using an open loop configuration where the variable frequency signal is not connected back to other components of the variable frequency generator. The variable frequency generator may include a direct digital synthesizer, an injection-locked synthesizer, or other appropriate synthesizers. A logic processor may also be included in the variable frequency generator. In some embodiments, the fast-hopping frequency synthesizer employs a direct modulation technique, and uses fast switching memory for controlling a voltage controlled oscillator. In some embodiments, the frequency synthesizer includes a feedback loop that comprises a digital to analog converter and/or a switch cap digital to analog converter and/or an (analog/digital) memory element (e.g. capacitor, RAM, etc) within a feedback loop.

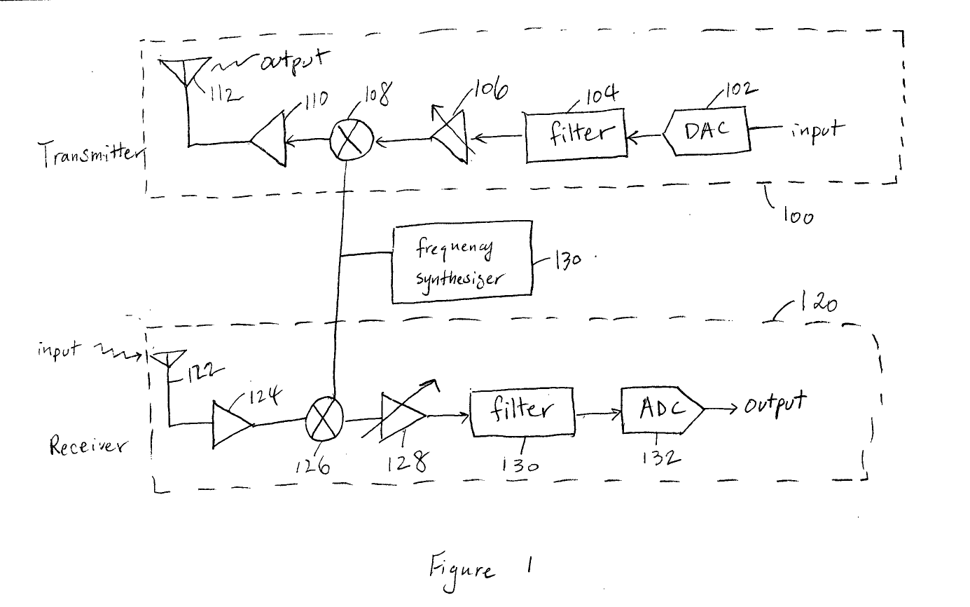

FIG. 1 is a system diagram of a high-speed transceiver embodiment. In this example, a signal to the transmitter is sent to transmitter 100. Digital to analog converter (DAC) 102 converts the input from digital to analog. The analog signal is fed to filter 104 and then an automatic level control (also referred to as a programmable gain amplifier) 106. A mixer 108 mixes the output of automatic level control 106 with a carrier frequency generated by frequency synthesizer 130. The mixer output is sent to a power amplifier 110, and transmitted via antenna 112.

The transceiver also includes a receiver 120. An input signal is received by the antenna 122 of the receiver and is sent to a low noise amplifier 124. In some embodiments, antenna 122 is the same physical antenna as 112 in the transmitter. The output of the low noise amplifier is mixed with a carrier frequency generated by the frequency synthesizer 130 using mixer 126.

The mixer output is sent to an automatic gain control (also referred to as a programmable gain amplifier) 128, and its output is sent to filter 130 and the analog to digital converter (ADC) 132 to obtain a final digital output. Mixer 108 modulates the baseband signal to its carrier frequency for transmission, and mixer 126 demodulates the signal from its carrier frequency down to baseband. Both the modulation and the demodulation components require a carrier frequency that is generated by frequency synthesizer 130. In this embodiment, the transceiver is used in high-speed applications such as ultrawide band (UWB) systems (for example, IEEE 802.15.3a, 802.15.4a, etc), where the carrier frequency hops from one channel to another quickly. Accordingly, the frequency synthesizer used in the system is preferably a fast-hopping frequency synthesizer. As used herein, a fast-hopping signal refers to a signal that switches from one channel to another within a time frame which is small relative to the PLL reference frequency input period, and a fast-hopping frequency synthesizer refers to a frequency synthesizer used to generate a fast-hopping signal.

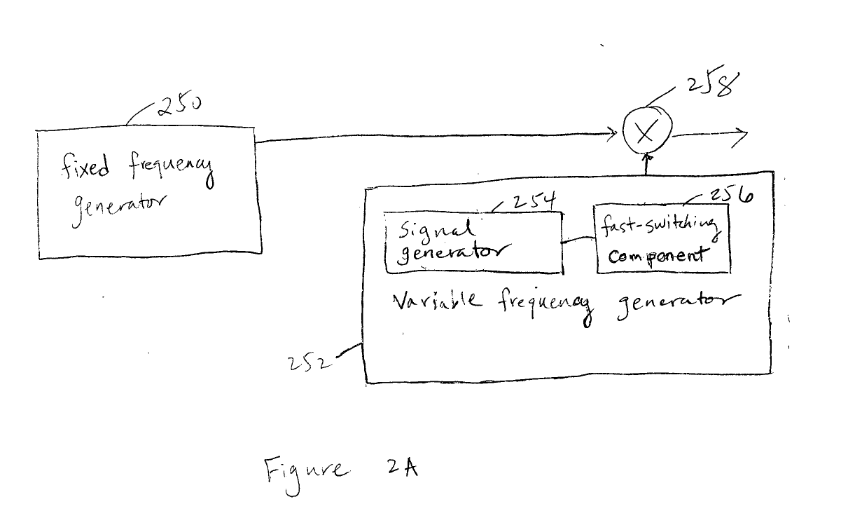

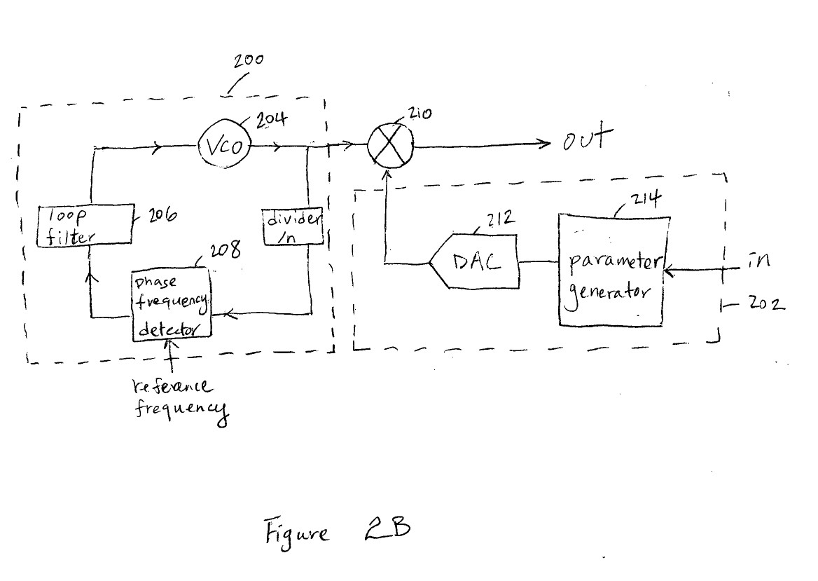

FIG. 2A is a block diagram illustrating a fast-hopping frequency synthesizer embodiment. The frequency synthesizer includes a fixed frequency generator 250 that outputs a radio frequency (RF) signal with a fixed frequency, and a variable frequency generator 252 that outputs a signal with frequencies that quickly varies. Mixer 258 combines the outputs of the fixed frequency generator and the variable frequency generator to provide a fast-hopping output. The variable frequency generator includes a signal generator 254 and a fast-switching component 256. In some embodiments, the fast-switching component provides configurations to the signal generator and is capable of switching between different configurations; in some embodiments, the signal generator provides signals with various frequencies and the fast-switching component operates on these signals. The fast-switching component performs its operations at a speed that allows the output to quickly hop from one frequency to another.

FIG. 2B is a block diagram illustrating another fast-hopping frequency synthesizer embodiment. The fast-hopping frequency synthesizer includes a fixed frequency generator 200, and a variable frequency generator 202. Mixer 210 combines the fixed frequency signal and the variable frequency signal to provide the synthesizer output. It is preferably a single-sideband mixer to provide better image rejection.

The fixed frequency RF synthesizer includes a VCO 204, a loop filter 206, a phase frequency detector (PFD) 208. The output of the PFD is a signal proportional to the phase difference between a referenced frequency and the output of the VCO. The output of the PFD is filtered by loop filter 206 and the filtered result is sent to VCO 204. The VCO is used to generate a fixed RF sine wave. The RF sine wave is mixed with another sine wave generated by variable frequency generator 202.

The variable frequency generator has a feed-forward circuit configuration where the variable frequency signal is not connected back to other components of the variable frequency generator. Unlike traditional PLL's with feedback loops which have a finite time constant when settling to a frequency change, the feed-forward configuration allows the variable frequency generator to more quickly change its output frequency. In some embodiments, the settling time of the variable frequency generator is substantially less than the settling time of the fixed frequency generator required when the fixed frequency generator is first configured.

In the embodiment shown in FIG. 2B, the variable frequency generator is a Direct Digital Synthesizer (DDS). The DDS is configurable to output a signal with different frequencies; the output of the DDS is mixed with the fixed frequency signal to provide different synthesizer output frequencies.

The DDS includes a parameter (e.g. I/Q sinewave) generator 214 and a DAC 212. The parameter generator configures the DAC, which generates an output signal with the desired frequency. There are a variety of techniques used to implement the parameter generator. In some embodiments, the parameter generator is implemented as a lookup table. To generate a signal of a desired frequency, information pertaining to the frequency is input into the lookup table, and the parameters corresponding to the desired frequency are located in the lookup table, and used to configure the DAC to synthesize the frequency desired. By digitally generating the variable frequency signal used for mixing, the DDS is capable of synthesizing signals that meet the precision and speed requirements of the fast-hopping systems. Because a broad range of frequencies can be synthesized by adjusting the DDS rather than the fixed frequency RF frequency synthesizer, this synthesizer architecture offers more flexibility.

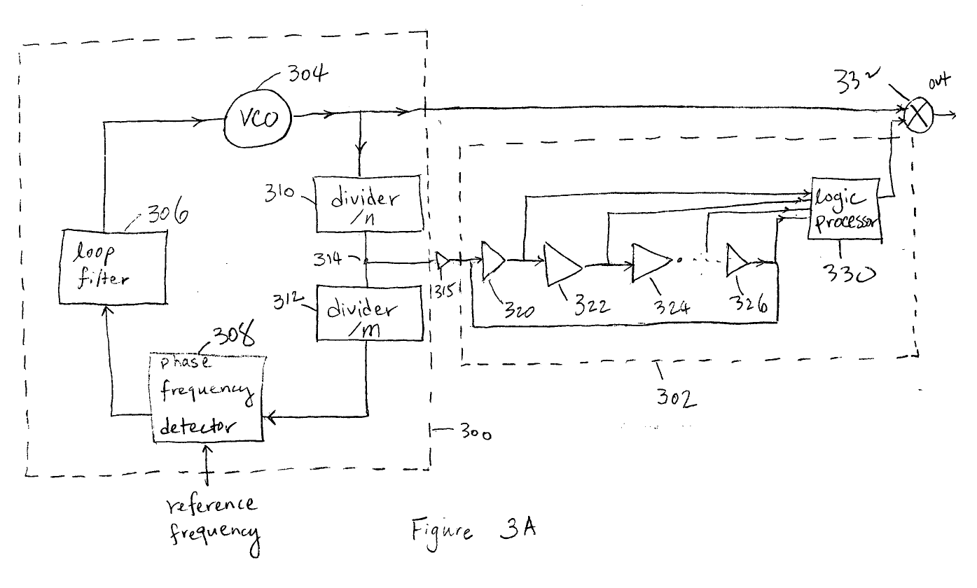

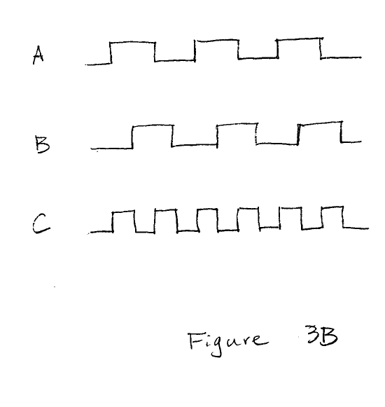

FIG. 3A is a block diagram illustrating another fast-hopping frequency synthesizer embodiment. In this example, a fixed frequency RF synthesizer 300 is used to generate a signal that is possibly a quadrature RF sine wave. This signal is mixed with a second sine wave generated by an injection-locked synthesizer 302. Different output frequencies are achieved by changing the output frequency of the injection-locked synthesizer. The fixed frequency RF synthesizer includes a phase frequency detector 308, a loop filter 306 and a VCO 304. The RF synthesizer also includes two dividers 310 and 312, set to divide their inputs by integer values m and n, respectively. In this embodiment, the divider values determine the frequency of the fixed frequency RF synthesizer taken at junction 314.

The output of the RF synthesizer is also referred to as the injection signal. It is buffered by buffer 315 and injected into the injection-locked synthesizer. The injection signal has a channel spacing that is approximately the expected channel spacing of the VCO output divided by k, where k is an integer. The injection locked synthesizer includes a ring oscillator and a logic processor. The ring oscillator includes several stages, including 320, 322, 324, and 326. The number of stages may vary for different implementations. In this example, during steady state operation of the ring oscillator, the phase change between the input of stage 320 and the output of stage 326 is an integer multiple of 360°; each stage thus introduces a phase delay. The output of each oscillator stage is fed forward to a logic processor 330. The logic processor is capable of quickly selecting oscillator stage outputs of different phases and combining them to obtain desired output frequency. Details of the logic processor's operations are discussed in

FIG. 3B. The output of the injection locked synthesizer is mixed with the RF synthesizer output by mixer 332.

FIG. 3B is a diagram illustrating the operations of logic processor 330 shown in FIG. 3A according to one embodiment. In this example, two signals, A and B, are combined by the logic processor to form a new signal, C. Signals A and B have the same frequency, and B has a 45° phase difference relative to A. The logic processor performs an exclusive-or (XOR) operation on A and B, to generate output C that has a frequency that is twice the frequency of A or B. It should be noted that the logic processor may select different number of signals and perform different types of logic operations to obtain desired output frequency.

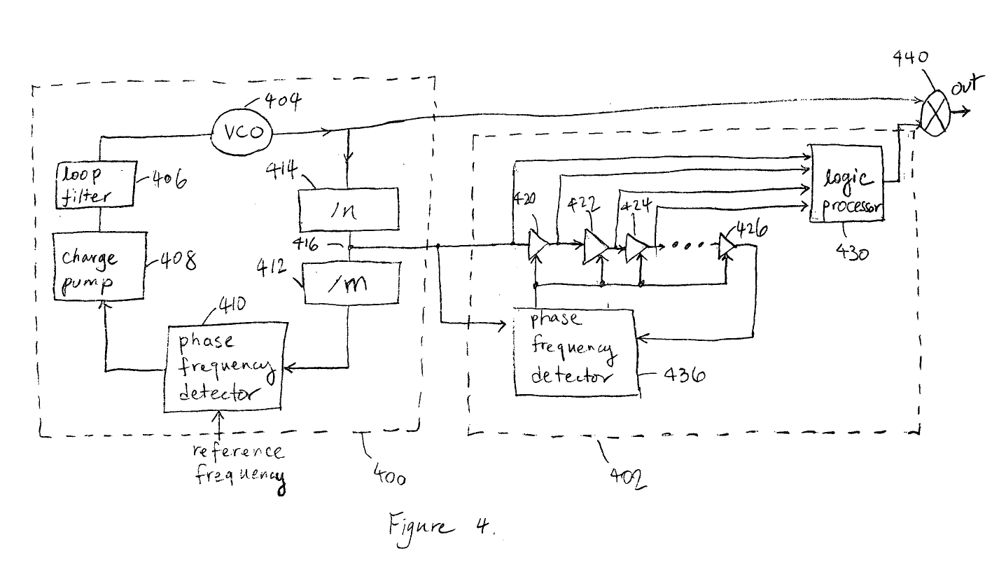

FIG. 4 is a block diagram illustrating another fast-hopping frequency synthesizer. A fixed frequency RF synthesizer 400 is used to generate a possibly quadrature RF sine wave that is mixed with a second sine wave generated by a variable frequency generator 402. The variable frequency generator includes a delayed locked loop (DLL) connected to a logic processor 430. The fixed frequency RF synthesizer includes VCO 404, loop filter 406, charge pump 408, phase frequency detector 410 and dividers 412 and 414. The signal taken at junction 416 has a channel spacing that is approximately a fraction of the system's channel spacing. In some embodiments, the fraction is an integer fraction or simple fraction. This signal is used to drive the DLL. Each of the delay stages of the DLL (420, 422, 424, 426, etc.) introduces a delay to its input. Thus, each of the delay stages outputs a signal that is a phase shifted version of the DLL's input. Phase frequency detector 436 compares the input and the output of the DLL, and adjusts the settings for the delay stages accordingly to control the output phase. The outputs of the DLL delay stages are fed forward to logic processor 430. The logic processor performs combinational logic on its inputs in a manner similar to the logic processor shown in FIG. 3A. The output of logic processor 430 and the output of the fixed frequency RF synthesizer are combined by mixer 440. The resulting signal is an RF sine wave with desired output frequency.

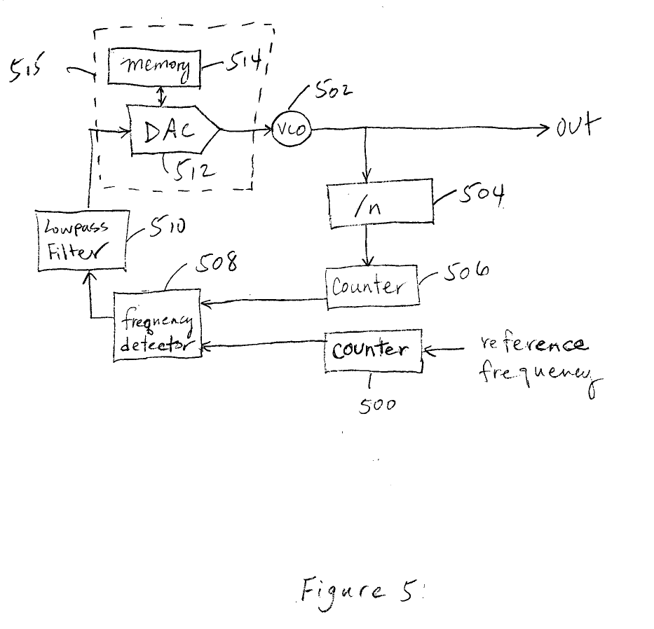

FIG. 5 is a block diagram illustrating another fast-hopping frequency synthesizer. Mixing is not required for this frequency synthesizer embodiment; rather, the frequency synthesizer employs a direct modulation technique. The output of VCO 502 is the output of the frequency synthesizer. The rest of the circuit forms a feedback loop to the VCO. The VCO's control voltage is provided by a VCO controller 515 that includes DAC 512 and memory 514. The VCO controller adjusts the VCO's configuration so the VCO generates different output frequencies.

The output frequency of the VCO is divided by N by a divider 504, where N is an appropriate value selected for the system to cause the desired frequency range to be generated in the output. The divided frequency is sent to counter 506. A reference frequency is sent to another counter 500. Counters 500 and 506 count their inputs for the same amount of time, and their respective outputs are sent to frequency detector 508. The frequency detector detects the frequency difference between its two inputs, and outputs a signal with a frequency that is proportional to the difference. The output of the frequency detector is filtered by a lowpass filter 510 and then used to adapt and update DAC 512 to achieve frequency lock. Using the counters allows the VCO output frequency to be measured with high precision. In some embodiments, counters 500 and 506 are omitted and the divided output and the reference frequency are compared directly by the frequency detector.

During the dwell time on a specific frequency, the feedback loop dynamically maintains lock and tracks out transient perturbations to the loop, as well as updates the DAC to obtain the desired output frequency. In some embodiments, the frequency synthesizer is trained to obtain outputs at various desired frequencies. The corresponding DAC configurations are stored in a memory 514. The memory is a component that is capable of storing the configuration, including registers, capacitors, random access memory (RAM), read-only memory (ROM), or any other appropriate component. Storing the configurations in memory enables the VCO controller to switch between different configurations at a speed that allows the VCO to provide a fast-hopping output, also referred to as the fast-hop switching speed. During operation, if the synthesizer's output is to hop to a new frequency, the corresponding DAC configuration is recalled and applied to the DAC. Digitally configuring the synthesizer loop allows for near instantaneous switching between frequencies.

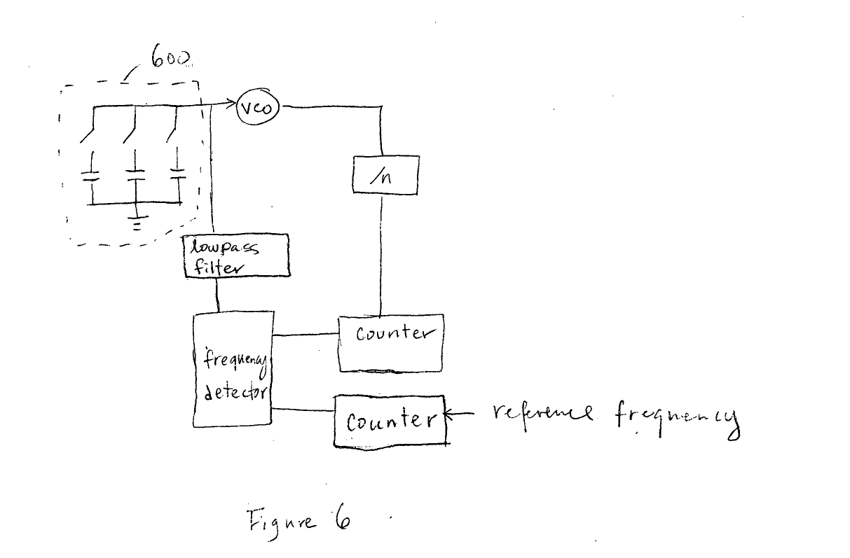

FIG. 6 is a block diagram illustrating another fast-hopping frequency synthesizer according to one embodiment of the present invention. The configuration of this frequency synthesizer embodiment is similar to the one shown in FIG. 5 with a few exceptions. The VCO controller shown in FIG. 6 includes a switch cap memory element 600 instead of the memory and DAC shown in FIG. 5. The switch cap analog memory element is comprised of multiple capacitors that can be connected to the circuit via switches. If connected, the stored charge on the capacitor applies a voltage to the VCO and configures its output. The capacitors in the switch cap DAC effectively serve as a memory for storing the configurations of the VCO. Multiple capacitors may be connected or disconnected to supply the appropriate voltages. The feedback loop adapts the VCO to maintain the desired output during dwell time.

An improved system and method for providing a fast-hopping signal have been disclosed. The techniques described provide a fast-hopping signal without significant increase in complexity and cost.

Although the foregoing embodiments have been described in some detail for purposes of clarity of understanding, the invention is not limited to the details provided. There are many alternative ways of implementing the invention. The disclosed embodiments are illustrative and not restrictive.

1. A frequency synthesizer comprising:
a fixed frequency generator configured to generate a fixed frequency signal;
a variable frequency generator configured to generate a variable frequency signal;
wherein the fixed frequency signal and the variable frequency signal are combined to provide a fast-hopping output signal.

2. A frequency synthesizer as recited in claim 1 wherein the variable frequency generator has an output that is not connected back to other components of the variable frequency generator.

3. A frequency synthesizer as recited in claim 1 wherein the variable frequency generator settles substantially faster than fixed frequency generator.

4. A frequency synthesizer as recited in claim 1 further comprising a mixer configured to combine the fixed frequency signal and the variable frequency signal.

5. A frequency synthesizer as recited in claim 1 wherein the frequency synthesizer is included in a transceiver.

6. A frequency synthesizer as recited in claim 1 wherein the frequency synthesizer is used in an ultra-wide band (UWB) system.

7. A frequency synthesizer as recited in claim 1 wherein the variable frequency generator includes a signal generator and a fast switching component for configuring the signal generator.

8. A frequency synthesizer as recited in claim 1 wherein the variable frequency generator includes a signal generator and a fast switching component for operating on a plurality of generated signals by the signal generator.

9. A frequency synthesizer as recited in claim 1 wherein the variable frequency generator includes a direct digital synthesizer.

10. A frequency synthesizer as recited in claim 1 wherein the variable frequency generator includes a direct digital synthesizer comprising:
a digital to analog converter (DAC);
a parameter generator coupled to the DAC;
wherein the parameter generator is configured to provide a configuration parameter to the DAC, and the DAC is configured to generate the variable signal based on the configuration parameter.

11. A frequency synthesizer as recited in claim 10 wherein the parameter generator includes a lookup table.

12. A frequency synthesizer as recited in claim 1 wherein the variable frequency generator includes an injection-locked synthesizer; and the fixed frequency signal is an input to the injection-locked synthesizer.

13. A frequency synthesizer as recited in claim 1 wherein the variable frequency generator includes an injection-locked synthesizer comprising:
a ring oscillator having a plurality of stages, where each of the plurality of stages has a stage output; and
a logic processor configured to perform operations on at least one of the stage outputs to obtain the variable frequency signal.

14. A frequency synthesizer as recited in claim 13, wherein the logic processor is configured to perform an exclusive-or operation.

15. A frequency synthesizer as recited in claim 1 wherein the variable frequency generator includes a delay locked loop.

16. A frequency synthesizer as recited in claim I wherein the variable frequency generator includes:
a delay locked loop having a plurality of stages, wherein each of the plurality of stages has a stage output; and
a logic processor configured to perform an operation on at least one of the stage outputs to obtain the variable frequency signal.

17. A fast-hopping frequency synthesizer comprising:
a voltage controlled oscillator (VCO) configured to generate a fast-hopping output signal; and
a VCO controller coupled to the VCO for providing a first VCO configuration and a second VCO configuration;
wherein the VCO controller switches between the first VCO configuration and the second VCO configuration at a fast-hop switching speed.

18. A frequency synthesizer as recited in claim 17 wherein the fast-hopping output signal is directly synthesized.

19. A frequency synthesizer as recited in claim 17 wherein the VCO controller comprises a memory for storing a configuration used to determine a VCO input.

20. A frequency synthesizer as recited in claim 17 further comprising a feedback loop coupled to the VCO, configured to adapt the VCO to provide a fast hopping signal.

21. A frequency synthesizer as recited in claim 17 further comprising a feedback loop coupled to the VCO, configured to adapt the VCO to provide a fast hopping signal;
wherein the feedback loop comprises a frequency detector configured to provide a feedback to the VCO controller.

22. A frequency synthesizer as recited in claim 17 further comprising a feedback loop coupled to the VCO, configured to adapt the VCO to provide a fast hopping signal;
wherein the feedback loop comprises a frequency detector configured to provide a feedback to the VCO controller, and the frequency detector detects a difference between a divided output and a divided reference frequency.

23. A frequency synthesizer as recited in claim 17 wherein the VCO controller comprises a digital to analog converter configured to control the VCO input.

24. A frequency synthesizer as recited in claim 17 wherein the VCO controller comprises a switch cap digital to analog converter configured to control the voltage controlled oscillator input.

25. A method for synthesizing a fast-hopping signal, comprising:
generating a fixed frequency signal;
generating a variable frequency signal; and
combining the fixed frequency signal and the variable frequency signal to provide the fast-hopping signal.

26. A method for synthesizing a fast-hopping signal, comprising:
providing a first voltage controlled oscillator (VCO) configuration to a VCO;
switching to a second VCO configuration at a fast-hopping switching speed; and
generating the fast-hopping signal.
